(19) United States
(12) Patent Application Publication
(10) Pub. No.: US 2026/0305149 A1
(43) Pub. Date: Oct. 1, 2026

(54) DISPLAY APPARATUS

(71) Applicant: LG Display Co., Ltd., Seoul (KR)

(72) Inventors: JaeKwang LEE, Paju-si (KR); Sanghun YOON, Paju-si (KR); Jongmoo HA, Paju-si (KR); Myeongsu KIM, Paju-si (KR); Dongmin LEE, Paju-si (KR)

(73) Assignee: LG Display Co., Ltd., Seoul (KR)

(21) Appl. No.: 19/435,132

(22) Filed: Dec. 29, 2025

(30) Foreign Application Priority Data
Mar. 25, 2025 (KR) 10-2025-0037844

(51) Int. Cl. H10K 59/88; H10K 59/131

(52) U.S. Cl. CPC H10K 59/88; H10K 59/131

(57) ABSTRACT

A display apparatus includes a substrate having a display pixel area, a dummy pixel area, and a non-display area. A plurality of pixels are disposed in the display pixel area and electrically connected to a gate line, a data line, a pixel driving power line, and an initialization voltage line. A plurality of dummy pixels are disposed in the dummy pixel area and electrically connected to a dummy gate line, the data line, the pixel driving power line, and a dummy initialization voltage line. An initialization voltage supply line is disposed in the non-display area and is electrically connected to the initialization voltage line in the display pixel area and to the dummy initialization voltage line, thereby preventing luminance deviation and improving image quality.

### CROSS-REFERENCE TO RELATED APPLICATION

This application claims the benefit of and priority to Korean Patent Application No. 10-2025-0037844 filed on Mar. 25, 2025, the entirety of which is hereby incorporated by reference for all purposes as if fully set forth herein.

### BACKGROUND

### Technical Field

The present disclosure relates to a display apparatus.

### Description of the Related Art

A display apparatus has been widely used as a display screen of various products such as portable electronic devices including smart phones and tablet PCs (personal computers), or the like, wearable devices such as smart watches, televisions, notebook computers, and monitors, or the like.

The display apparatus used as the display screen in wearable devices such as the smart watch may be configured to display an image by light emission of light emitting devices configured in each of a plurality of pixels which are disposed in a display area.

Recently, as the appearance and design of wearable devices have become important, research and development have been conducted on a display apparatus in which corners of a display area are configured in a curved shape.

### BRIEF SUMMARY

The display apparatus used as display screen in wearable devices includes dummy pixels. The dummy pixels may be disposed in a dummy pixel area at least partly adjacent to the display area. The dummy pixels may be maintained in an electrically floating state to maintain process uniformity during a manufacturing process.

A block dim effect occurs due to luminance deviation which might be caused by non-uniformity of a data signal (or voltage) applied to the display area due to interference between a signal line which is disposed in the display area via the dummy pixel area and the dummy pixels in the electrically floating state.

The inventors of the present disclosure have recognized the above-mentioned block dim effect and have performed extensive research and experiments on a display apparatus capable of preventing or minimizing the block dim effect caused by the luminance deviation due to the dummy pixels. Through extensive research and experiments, the inventors of the present disclosure have invented a display apparatus capable of improving image quality even though the dummy pixels are included.

To be specific, the present disclosure relates to a display apparatus that prevents block dim, a luminance deviation issue caused by interference between data lines and electrically floating dummy pixels. This is achieved through the use of dummy line connection bridges that connect dummy initialization voltage and gate lines to fixed voltage supply lines, stabilizing the electrical environment around the display area. In addition, certain dummy transistors are formed without semiconductor layers or are insulated from data lines, thereby eliminating unwanted current paths that previously resulted in non-uniform luminance and reduced image quality.

The display employs a hybrid thin film transistor structure combining low temperature polysilicon and oxide semiconductors. The low temperature polysilicon transistors are used for high speed control elements, while the oxide transistors serve in driving and initialization roles to reduce leakage currents. Some transistors share control signals, which simplifies the circuit design, reduces the complexity of the gate driver, and improves power efficiency.

The structural design supports curved display areas suitable for wearable devices and incorporates a time division data output circuit that minimizes pad count and substrate width, enabling slimmer bezels and greater curvature. These features improve luminance uniformity and image quality while contributing to environmental, social, and governance performance by reducing power consumption and optimizing manufacturing energy use.

One or more aspects of the present disclosure are directed to providing a display apparatus capable of preventing or minimizing block dim effect caused by luminance deviation due to dummy pixels.

One or more aspects of the present disclosure are directed to providing a display apparatus capable of improving image quality.

One or more aspects of the present disclosure are directed to providing a display apparatus capable of improving luminance and realizing ESG (Environmental, Social, and Governance) performance by reducing power consumption by high luminance.

One or more aspects of the present disclosure are directed to providing a display apparatus capable of realizing ESG (Environmental, Social, and Governance) performance by reducing production energy through process optimization.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a display apparatus according to an embodiment of the present disclosure comprises a substrate including a display pixel area having a corner curved portion, a dummy pixel area adjacent to the display pixel area, and a non-display area adjacent to the dummy pixel area; a plurality of pixels disposed at the display pixel area and electrically connected to a gate line, a data line, a pixel driving power line, and an initialization voltage line; a plurality of dummy pixels disposed at the dummy pixel area and electrically connected to a dummy gate line, the data line, the pixel driving power line, and a dummy initialization voltage line; an initialization voltage supply line disposed at the non-display area and electrically connected to the initialization voltage line disposed at the display pixel area and to the dummy initialization voltage line.

According to another aspect a display apparatus comprises a substrate including a display pixel area having a corner curved portion, a dummy pixel area adjacent to the display pixel area, and a non-display area adjacent to the dummy pixel area; a plurality of pixels disposed at the display pixel area and electrically connected to a gate line, a data line, and an initialization voltage line; a plurality of first dummy pixels disposed at the dummy pixel area and electrically connected to the gate line, the data line, and the initialization voltage line; and a plurality of second dummy pixels disposed at the dummy pixel area and electrically connected to a dummy gate line, the data line, and a dummy initialization voltage line.

In one or more embodiments, a display apparatus may comprise a substrate including a display pixel area having a corner curved portion, a dummy pixel area adjacent to the display pixel area, and a non-display area adjacent to the dummy pixel area; a plurality of pixels disposed in the display pixel area and electrically connected to a gate line, a data line, a pixel driving power line, and an initialization voltage line; a plurality of dummy pixels disposed in the dummy pixel area and electrically connected to a dummy gate line, the data line, the pixel driving power line, and a dummy initialization voltage line; and an initialization voltage supply line disposed in the non-display area and electrically connected to the initialization voltage line disposed in the display pixel area. The dummy initialization voltage line may be electrically connected to the initialization voltage supply line so that an initialization voltage supplied through the initialization voltage supply line is applied to the dummy initialization voltage line. The dummy initialization voltage line may be maintained at a constant voltage.

Details of other exemplary embodiments will be included in the detailed description of the disclosure and the accompanying drawings.

According to one or more aspects of the present disclosure, since block dim caused by luminance deviation due to dummy pixels may be prevented or minimized, thereby providing a display apparatus with improved image quality.

According to one or more aspects of the present disclosure, the luminance of the display apparatus may be improved, thereby realizing ESG (Environmental, Social, and Governance) performance by reducing power consumption due to high luminance of the display apparatus.

According to one or more aspects of the present disclosure, ESG (Environmental, Social, and Governance) performance by reducing production energy through process optimization may be realized.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure. However, the technical features of the present embodiment are not limited to those shown in the specific drawings, and the features disclosed in each drawing may be combined to form a new embodiment.

FIG. 1 is a diagram schematically illustrating a configuration of a display apparatus according to an embodiment of the present disclosure.

FIG. 2 is an enlarged view of a portion “A” illustrated in FIG. 1.

FIG. 3 is an equivalent circuit diagram illustrating configurations of a pixel, a first dummy pixel, and a second dummy pixel in a display apparatus according to an embodiment of the present disclosure.

FIG. 4 is plan views respectively illustrating layout structures of a pixel circuit and a dummy pixel circuit according to an embodiment of the present disclosure.

FIG. 5 is cross-sectional views respectively illustrating structures of a pixel, a first dummy pixel, and a second dummy pixel illustrated in FIG. 4.

FIG. 6 is an enlarged view of a portion “B” illustrated in FIG. 1.

FIG. 7 is an enlarged view of a portion “C” illustrated in FIG. 1.

FIG. 8 is a diagram illustrating a barrier pixel part illustrated in FIG. 7.

Throughout the drawings and the detailed description, unless otherwise described, the same drawing reference numerals should be understood to refer to the same elements, features, and structures.

### DETAILED DESCRIPTION

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present disclosure are used, another part may be added unless “only” is used. The terms of a singular form can include plural forms unless referred to the contrary.

In construing an element, the element is construed as including an error range although there is no explicit description.

The phrase “A filled in B” does not imply that A is exclusively contained within B to the exclusion of other materials. Instead, it is intended to encompass a broad range of conditions, including but not limited to “partially filled in,” “substantially filled in,” “completely filled in,” and “exclusively filled in.” Similarly, the phrase “B filled with A” does not suggest that B is exclusively filled with A, excluding other materials. Rather, it covers various degrees of filling, such as “partially filled with,” “substantially filled with,” “completely filled with,” and “exclusively filled with.”

For the expression that an element is “connected”, “coupled”, “contact”, or “attach” to another element, the element may not only be directly connected, coupled, or contacted to another element, but also be indirectly connected, coupled, contacted, or attached to another element with one or more intervening elements interposed between the elements, unless otherwise specified.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

For the expression that an element is “contacts” or “overlaps” with another element, the element can not only directly contact, overlap, or the like with another element, but also indirectly contact or overlap with another element with one or more intervening elements disposed or interposed between the elements, unless otherwise specified.

“A first direction”, “a second direction”, “a third direction”, “X-axis direction”, “Y-axis direction”, and “Z-axis direction” should not be construed by a geometric relation only of a mutual vertical relation and may have broader directionality within the range that elements of the present disclosure may act functionally.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, example embodiments of a display apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

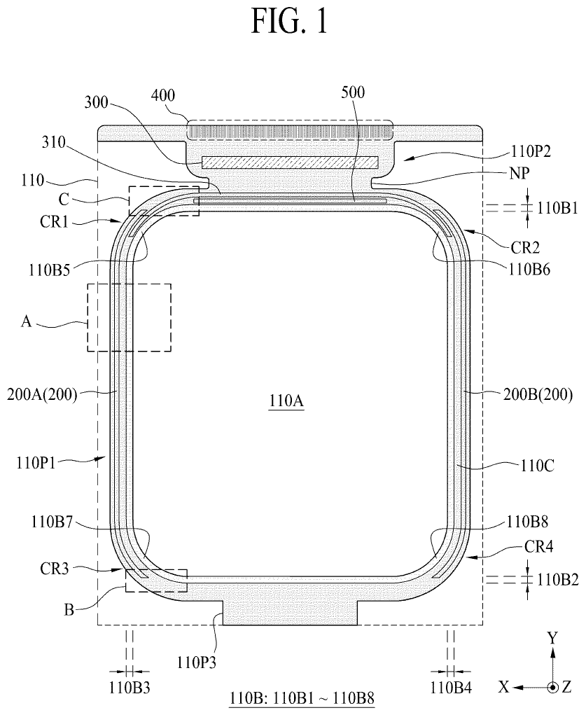

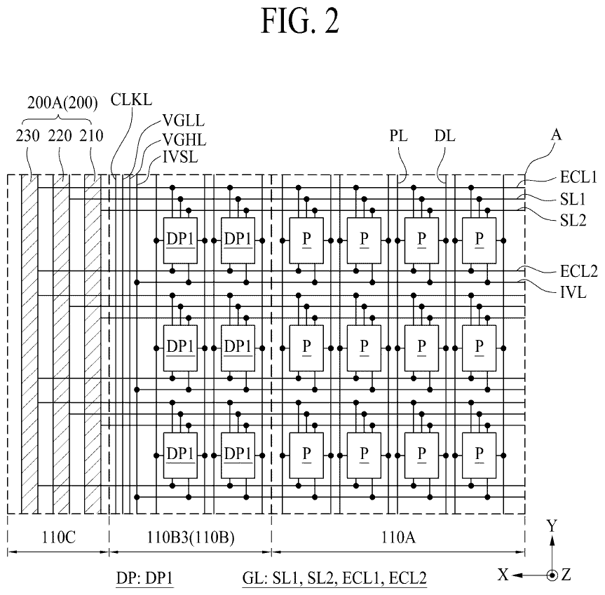

FIG. 1 is a diagram schematically illustrating a configuration of a display apparatus according to an embodiment of the present disclosure. FIG. 2 is an enlarged view of a portion “A” illustrated in FIG. 1.

The display apparatus according to an embodiment of the present disclosure may be a light emitting display apparatus. For example, the light emitting display apparatus may be any one of an organic light emitting display apparatus, a quantum dot light emitting display apparatus, and an inorganic light emitting display apparatus.

Referring to FIGS. 1 and 2, the display apparatus according to an embodiment of the present disclosure may include a substrate 110 having a plurality of sub-pixels P and a plurality of dummy pixels DP disposed thereon.

The substrate 110 may be made of a plastic material or a glass material. For example, the substrate 110 may include one or more plastic material layers.

The substrate 110 may include a screen portion 110P1 including one or more corner curved portions (or corner rounding portions) CR1 to CR4. The screen portion 110P1 may include a rectangular shape including four corner curved portions CR1 to CR4. For example, wherein the number of curved portions is not limited.

The substrate 110 may further include an extension portion 110P2 extending from the screen portion 110P1. The extension portion 110P2 may extend from one side (or a first side) of the screen portion 110P1 so as to have a width relatively smaller than that of the screen portion 110P1. For example, the substrate 110 may further include a neck portion NP. The neck portion NP may be formed between the screen portion 110P1 and the extension portion 110P2 and may have a width smaller than that of the extension portion 110P2. The neck portion NP may be a bending portion, and thereby, the extension portion 110P2 may be bent to a rear surface of the substrate 110 by bending of the neck portion NP.

The extension portion 110P2 and the neck portion NP may extend from the first side of the screen portion 110P1 between a first corner curved portion CR1 and a second corner curved portion CR2 among the four corner curved portions CR1 to CR4 of the substrate 110.

The substrate 110 may further include a protrusion portion 110P3 protruding from a second side of the screen portion 110P1. The protrusion portion 110P3 may protrude from the other side (or a second side) of the screen portion 110P1 so as to have a width relatively smaller than that of the screen portion 110P1. For example, the protrusion portion 110P3 may be omitted. For example, the protrusion portion 110P3 may extend from the second side of the screen portion 110P1 between a third corner curved portion CR3 and a fourth corner curved portion CR4 among the four corner curved portions CR1 to CR4 of the substrate 110.

The substrate 110 may have a rectangular shape in a manufacturing process and may have a shape corresponding to the screen portion 110P1, the extension portion 110P2, and the protrusion portion 110P3 by a scribing process (or a trimming process). For example, the substrate 110 including the screen portion 110P1, the extension portion 110P2, and the protrusion portion 110P3 may be implemented by cutting (or separating) from a base substrate having a rectangular shape. For example, an outer wall of the substrate 110 including the screen portion 110P1, the extension portion 110P2, the neck portion NP, and the protrusion portion 110P3 may correspond to a trimming line.

The substrate 110 may include a display pixel area 110A, a dummy pixel area 110B, and a non-display area 110C.

The display pixel area 110A may include corner curved portions (or corner portions) corresponding to the corner curved portions CR1 to CR4. The display pixel area 110A may be defined (or provided) in the screen portion 110P1 of the substrate 110. For example, the display pixel area 110A may include a central portion of the screen portion 110P1. For example, the display pixel area 110A may have a quadrangular shape or a rectangular shape having corner curved portions, but is not limited thereto, and may have a square shape or a circular shape.

The dummy pixel area 110B may be defined (or provided) in the screen portion 110P1 of the substrate 110 so as to surround the display pixel area 110A. The dummy pixel area 110B may include curved portions corresponding to corner curved portions CR1 to CR4 and may include a shape corresponding to the display pixel area 110A in a plan view.

The dummy pixel area 110B according to an embodiment of the present disclosure may include first to eighth dummy pixel areas 110B1 to 110B8.

The first dummy pixel area (or a lower dummy area) 110B1 may be adjacent to a first side (or a lower side) of the display pixel area 110A. The second dummy pixel area (or an upper dummy area) 110B2 may be adjacent to a second side (or an upper side) of the display pixel area 110A. The third dummy pixel area (or a left dummy area) 110B3 may be adjacent to a third side (or a left side) of the display pixel area 110A. The fourth dummy pixel area (or a right dummy area) 110B4 may be adjacent to a fourth side (or a right side) of the display pixel area 110A.

The fifth dummy pixel area (or a first corner dummy area) 110B5 may be adjacent to a first corner curved portion of the display pixel area 110A. For example, the fifth dummy pixel area 110B5 may be adjacent to the first corner curved portion between the first side and the third side of the display pixel area 110A. For example, the fifth dummy pixel area 110B5 may be provided (or defined) in a curved shape at a corner portion (or first corner portion) between the first dummy pixel area 110B1 and the third dummy pixel area 110B3.

The sixth dummy pixel area (or a second corner dummy area) 110B6 may be adjacent to a second corner curved portion of the display pixel area 110A. For example, the sixth dummy pixel area 110B6 may be adjacent to the second corner curved portion between the first side and the fourth side of the display pixel area 110A. For example, the sixth dummy pixel area 110B6 may be provided (or defined) in a curved shape at a corner portion (or a second corner portion) between the first dummy pixel area 110B1 and the fourth dummy pixel area 110B4.

The seventh dummy pixel area (or a third corner dummy area) 110B7 may be adjacent to a third corner curved portion of the display pixel area 110A. For example, the seventh dummy pixel area 110B7 may be adjacent to a third corner curved portion between the second side and the third side of the display pixel area 110A. For example, the seventh dummy pixel area 110B7 may be provided (or defined) in a curved shape at a corner portion (or third corner portion) between the second dummy pixel area 110B2 and the third dummy pixel area 110B3.

The eighth dummy pixel area (or a fourth corner dummy area) 110B8 may be adjacent to a fourth corner curved portion of the display pixel area 110A. For example, the eighth dummy pixel area 110B8 may be adjacent to the fourth corner curved portion between the second side and the fourth side of the display pixel area 110A. For example, the eighth dummy pixel area 110B8 may be provided (or defined) in a curved shape at a corner portion (or a fourth corner portion) between the second dummy pixel area 110B2 and the fourth dummy pixel area 110B4.

The non-display area 110C may be defined (or provided) in the screen portion 110P1, the extension portion 110P2, the neck portion NP, and the protrusion portion 110P3 of the substrate 110 so as to surround the dummy pixel area 110B. For example, the non-display area 110C may include all remaining regions of the substrate 110 other than the display pixel area 110A and the dummy pixel area 110B among the substrate 110. For example, the dummy pixel area 110B may be included in the non-display area 110C, and in this case, the non-display area 110C may include all remaining regions of the substrate 110 other than the display pixel area 110A among the substrate 110.

The plurality of pixels P may be disposed (or configured) in the display pixel area 110A to display an image. The plurality of pixels P may be disposed (or configured) along a first direction X (or a horizontal line) and a second direction Y (or a vertical line) intersecting the first direction X, and may be, for example, disposed in a matrix form. At least three adjacent pixels among the plurality of pixels P may configure one unit pixel. For example, the one unit pixel may include first to third pixels P that emit light of different colors from each other. For example, the first pixel P may be a red pixel emitting red light, the second pixel P may be a green pixel emitting green light, and the third pixel P may be a blue pixel emitting blue light, but is not limited thereto. For example, the one unit pixel may further include a fourth pixel emitting white light.

Each of the plurality of pixels P may be disposed (or configured) to be connected to a pixel driving line and may be configured to emit light based on a signal supplied from the pixel driving line. Each of the plurality of pixels P may be configured to be electrically connected to the pixel driving line including a gate line GL, a data line DL, a pixel driving power line PL, and an initialization voltage line IVL. Each of the plurality of pixels P may include a light emitting device, and a pixel circuit (or a first pixel circuit) having a plurality of thin-film transistors which are connected to the pixel driving line to independently drive the light emitting device.

According to an embodiment of the present disclosure, the display pixel area 110A may include a plurality of gate lines GL disposed parallel to the first direction X, a plurality of data lines DL disposed parallel to the second direction Y, a plurality of pixel driving power lines PL disposed parallel to the plurality of data lines DL, and a plurality of initialization voltage lines IVL disposed parallel to the plurality of gate lines GL. One pixel P may be provided (or configured) in an intersection region of the gate line GL and the data line DL.

Each of the plurality of gate lines GL may include a first scan line SL1, a second scan line SL2, a first emission control line ECL1, and a second emission control line ECL2.

Each of the plurality of initialization voltage lines IVL may be commonly connected to an initialization voltage supply line IVSL which is disposed along the non-display area 110C of the substrate 110. The initialization voltage supply line IVSL may run parallel to the second direction Y or the second direction Y in the dummy pixel area 110B.

The plurality of dummy pixels DP may be disposed (or configured) in a dummy pixel area 110B surrounding the display pixel area 110A to maintain process uniformity during a manufacturing process of the display apparatus.

The plurality of dummy pixels DP may be disposed (or configured) in the dummy pixel area 110B and may be configured not to display an image. For example, each of the plurality of dummy pixels DP may be disposed (or configured) without including a light emitting device, unlike the pixels P disposed in the display pixel area 110A.

The plurality of dummy pixels DP may be disposed (or configured) along an outermost portion of the display pixel area 110A so as to surround outermost pixels P disposed in the outermost portion of the display pixel area 110A. For example, one or more dummy pixels DP may be disposed in the dummy pixel area 110B adjacent to the outermost pixels P along the second direction Y. The number of dummy pixels DP disposed on each horizontal line may be a same e.g. outside the corner portions or different in the corner portion based on a curvature of the corner curved portion of the display pixel area 110A. Dummy pixels DP disposed in the dummy pixel area 110B corresponding to the corner curved portion of the display pixel area 110A will be described below.

Each of the plurality of dummy pixels DP, unlike the plurality of pixels P disposed in the display pixel area 110A, may be configured not to display an image, but rather to maintain process uniformity during the manufacturing process of the display apparatus and/or to prevent static electricity from an outside being transferred to the plurality of pixels P (or outermost pixels) disposed in the display pixel area 110A. For example, the plurality of dummy pixels DP may serve as an electrostatic discharge (ESD) protection circuit. The dummy pixels DP may either not have the light emitting device OLED or the OLED is not connected to the dummy pixel circuit. Thus, the dummy pixel may not be able to emit light.

Some of the plurality of dummy pixels DP may be configured to be electrically connected to a dummy pixel driving line including a dummy gate line and a dummy initialization voltage line, a data line DL, and a pixel driving power line PL. Some of the plurality of dummy pixels DP may include a dummy pixel circuit (or a second pixel circuit) having a plurality of thin-film transistors which are connected to the dummy pixel driving line, the data line, and the pixel driving power line.

According to an embodiment of the present disclosure, a plurality of first dummy pixels DP1 included in a first group among the plurality of dummy pixels DP may be connected to the pixel driving line in a same (or same manner) as the plurality of pixels P, and unlike the plurality of pixels P, may be disposed (or configured) not to display an image. For example, the plurality of first dummy pixels DP1 may be dummy pixels DP disposed to correspond to each horizontal line of the display pixel area 110A among the plurality of dummy pixels DP. For example, the plurality of first dummy pixels DP1 may include dummy pixels DP electrically connected to each of the plurality of gate lines disposed in the display pixel area 110A among the plurality of dummy pixels DP. For example, the plurality of first dummy pixels DP1 may be disposed (or configured) across an entire portion of the third and fourth dummy pixel areas 110B3 and 110B4, and a partial portion of each of the fifth to eighth dummy pixel areas 110B5, 110B6, 110B7, and 110B8.

The plurality of first dummy pixels DP1 may be configured to be electrically connected to the pixel driving line including the gate line GL, the data line DL, the pixel driving power line PL, and the initialization voltage line IVL which are disposed in the display pixel area 110A. The plurality of first dummy pixels DP1 may include a pixel circuit (or a dummy pixel circuit) having a plurality of thin-film transistors which are connected to the pixel driving line, but unlike the plurality of pixels P, may not include the light emitting device.

According to an embodiment of the present disclosure, a plurality of second dummy pixels included in a second group among the plurality of dummy pixels DP may be electrically connected to a dummy pixel driving line including the dummy gate line and the dummy initialization voltage line, the data line DL, and the pixel driving power line PL, and may be disposed (or configured) not to display an image, unlike the plurality of pixels P. For example, the plurality of second dummy pixels may be dummy pixels DP adjacent to each of first and last horizontal lines of the display pixel area 110A among the plurality of dummy pixels DP. For example, the plurality of second dummy pixels may include dummy pixels DP not electrically connected to each of the plurality of gate lines which are disposed in the display pixel area 110A among the plurality of dummy pixels DP.

The plurality of second dummy pixels may be disposed (or configured) in the first and second dummy pixel areas 110B1 and 110B2. The plurality of second dummy pixels may be disposed (or configured) across an entire portion of the first and second dummy pixel areas 110B1 and 110B2, and remaining portions of the fifth to eighth dummy pixel areas 110B5, 110B6, 110B7, and 110B8. For example, the plurality of second dummy pixels may include dummy pixels DP not electrically connected to each of the plurality of gate lines disposed in the display pixel area 110A among the plurality of dummy pixels DP which are disposed in the first and second dummy pixel areas 110B1 and 110B2 and the fifth to eighth dummy pixel areas 110B5, 110B6, 110B7, and 110B8.

The plurality of second dummy pixels may be configured to be electrically connected to the dummy pixel driving line including the dummy gate line and the dummy initialization voltage line, the data line DL, and the pixel driving power line PL. Each of the plurality of second dummy pixels may include a dummy pixel circuit (or a second pixel circuit) having a plurality of thin-film transistors which are connected to the dummy pixel driving line, the data line, and the pixel driving power line, but unlike the plurality of pixels P, may not include a light emitting device.

According to an embodiment of the present disclosure, the dummy pixel area 110B may include a plurality of dummy gate lines disposed parallel to the first direction X and a plurality of dummy initialization voltage lines disposed parallel to the plurality of dummy gate lines. One dummy pixel P may be provided (or configured) in an intersection region of the dummy gate line and the data line DL.

Each of the plurality of gate lines (or the plurality of dummy gate lines) may include a first dummy scan line, a second dummy scan line, a first dummy emission control line, and a second dummy emission control line.

The dummy pixel driving line may be disposed (or configured) in the dummy pixel area 110B and may be maintained in an electrically floating state, so that the dummy pixel circuit disposed in each of the plurality of second dummy pixels may be maintained in an electrically floating state.

The dummy pixel driving line may be disposed (or configured) in the dummy pixel area 110B to cross (or intersect) the data line DL and the pixel driving power line PL electrically connected to the plurality of dummy pixels DP. Each of the data line DL and the pixel driving power line PL may be disposed in the display pixel area 110A via the first dummy pixel area 110B1 and may extend to the second dummy pixel area 110B2. The dummy pixel driving line will be described below.

The display apparatus according to an embodiment of the present disclosure may further include a gate driving circuit 200, a driving integrated circuit 300, and a pad part 400.

The gate driving circuit 200 may be disposed in the non-display area 110C of the substrate 110 and may be configured to drive only the plurality of gate lines GL disposed in the display pixel area 110A. The gate driving circuit 200 may be electrically connected only to the plurality of gate lines GL disposed in the plurality of first dummy pixels DP1 and the plurality of pixels P. For example, the plurality of second dummy pixels among the plurality of dummy pixels DP may be configured not to be electrically connected to the gate driving circuit 200. For example, the plurality of first dummy pixels DP1 among the plurality of dummy pixels DP may be disposed between the display pixel area 110A and the gate driving circuit 200. Accordingly, the plurality of first dummy pixels DP1 may be electrically connected to the gate driving circuit 200, but do not include a light emitting device, and thus, do not emit light based on driving of the plurality of gate lines GL.

The gate driving circuit 200 may be configured to drive the plurality of gate lines GL in response to gate driving control signals including a plurality of clock signals supplied through a plurality of clock signal lines CLKL and gate driving voltages supplied through gate driving voltage lines VGHL and VGLL, or the like. For example, the gate driving voltages may include a gate high voltage and a gate low voltage. For example, the gate driving voltage lines VGHL and VGLL may include a gate high voltage supply line VGHL for supplying the gate high voltage to the gate driving circuit 200 and a gate low voltage supply line VGLL for supplying the gate low voltage to the gate driving circuit 200. The gate driving circuit 200 may be directly formed (or embedded) on the substrate 110 in a gate-in-panel (GIP) scheme together with thin-film transistors of the plurality of pixels P.

According to an embodiment of the present disclosure, the gate driving circuit 200 may be disposed to face each other with the display pixel area 110A therebetween. For example, the gate driving circuit 200 may be disposed in the non-display areas 110C corresponding to one side edge portion and the other side edge portion of the substrate 110. For example, the gate driving circuit 200 may include a first gate driving circuit 200A disposed (or configured) in the non-display area 110C on the third side of the screen portion 110P1 and a second gate driving circuit 200B disposed (or configured) in the non-display area 110C on the fourth side of the screen portion 110P1.

Each of the first gate driving circuit 200A and the second gate driving circuit 200B may be configured to drive the plurality of gate lines GL disposed in the display pixel area 110A in response to the gate driving control signal. The first gate driving circuit 200A and the second gate driving circuit 200B may be configured to drive the plurality of gate lines GL disposed in the plurality of first dummy pixels DP1 and the plurality of pixels P.

Each of the first gate driving circuit 200A and the second gate driving circuit 200B may include a first scan driving circuit 210, a second scan driving circuit 220, and an emission control driving circuit 230.

The first gate driving circuit 200A and the second gate driving circuit 200B may have curved portion in the area of the curved portion CR1-CR4.

The first scan driving circuit 210 may be configured to supply a first scan signal to the first scan line SL1 of each of the plurality of gate lines GL in response to the gate driving control signal.

The second scan driving circuit 220 may be configured to supply a second scan signal to the second scan line SL2 of each of the plurality of gate lines GL in response to the gate driving control signal.

The emission control driving circuit 230 may be configured to supply a first emission control signal to the first emission control line ECL1 of each of the plurality of gate lines GL and a second emission control signal to the second emission control line ECL2 of each of the plurality of gate lines GL in response to the gate driving control signal. For example, in the emission control driving circuit 230, an emission control signal which is output during an N−2^{th} period of a predetermined time may be applied to the second emission control line ECL2, and an emission control signal which is output during an N^{th} period of the predetermined time may be applied to the first emission control line ECL1, but is not limited thereto.

The number of each of the first scan driving circuits 210, the second scan driving circuits 220, and the emission control driving circuits 230 according to an embodiment of the present disclosure may be variously varied depending on the number of thin-film transistors configuring the pixel circuit of the pixel P.

The driving integrated circuit 300 may be configured to supply data signals to the plurality of data lines DL formed on the substrate 110 using an image data, data control signals, and driving voltages which are supplied from a display driving part (or a host system) through the pad part 400 (or a display pad part or a first pad part). The driving integrated circuit 300 may be an integrated circuit which is mounted in a chip mounting region provided in the extension portion 110P2 of the substrate 110. The driving integrated circuit 300 may be configured to align the image data inputted in response to a data control signal to suit a pixel arrangement structure disposed in the display pixel area 110A to generate pixel data for each pixel, convert the generated pixel data for each pixel into a data signal, and supply the data signal for each pixel to the plurality of data lines DL.

The pad part 400 may be provided in the extension portion 110P2 of the substrate 110 and may be electrically connected to the display driving part. The pad part 400 may be configured to receive image data, data control signals, driving voltages, and gate driving control signals from the display driving part.

The display apparatus according to an embodiment of the present disclosure may further include a time-division data output part 310.

The time-division data output part 310 may be disposed between the driving integrated circuit 300 and the plurality of data lines DL and may be configured to sequentially supply the data signals supplied from the driving integrated circuit 300 to the plurality of data lines DL in a time-divided manner. For example, the time-division data output part 310 may be configured to include a plurality of multiplexers for time-division driving the plurality of pixels P configuring one unit pixel in response to a data selection signal. For example, one multiplexer may be electrically connected to one channel of the driving integrated circuit 300 and electrically connected to three data lines DL configuring the one unit pixel. Accordingly, according to an embodiment of the present disclosure, the number of data pads provided in the pad part 400 that correspond to the plurality of data lines DL may be reduced to the number of multiplexers configuring the time-division data output part 310, thereby reducing a width of the neck portion NP, and thus, curvature of the first and second corner curved portions CR1 and CR2 of the substrate 110 may be reduced.

The first gate driving circuit 200A and the second gate driving circuit 200B may partly overlap with the time-division data output part 310 in end portion of the time-division data output part 310 being located in the curved portions CR1 and CR2.

The display apparatus according to an embodiment of the present disclosure may further include a touch sensor disposed on the display pixel area 110A of the substrate 110.

The touch sensor may be configured as a separate touch panel disposed on the display pixel area 110A, or as a touch sensor array including a touch electrode layer directly formed on the display pixel area 110A. The touch sensor may be configured to sense a user touch based on a mutual capacitance scheme or self-capacitance scheme.

The touch sensor according to an embodiment of the present disclosure may include a plurality of touch electrodes and a plurality of touch routing lines extending from each of the plurality of touch electrodes. The substrate 110 may further include a touch pad part disposed on a protruding portion 110P3. The touch pad part may include a plurality of touch electrode pads individually connected to the plurality of touch routing lines, but is not limited thereto. For example, the protruding portion 110P3 of the substrate 110 may be configured to support the touch pad part of the touch panel.

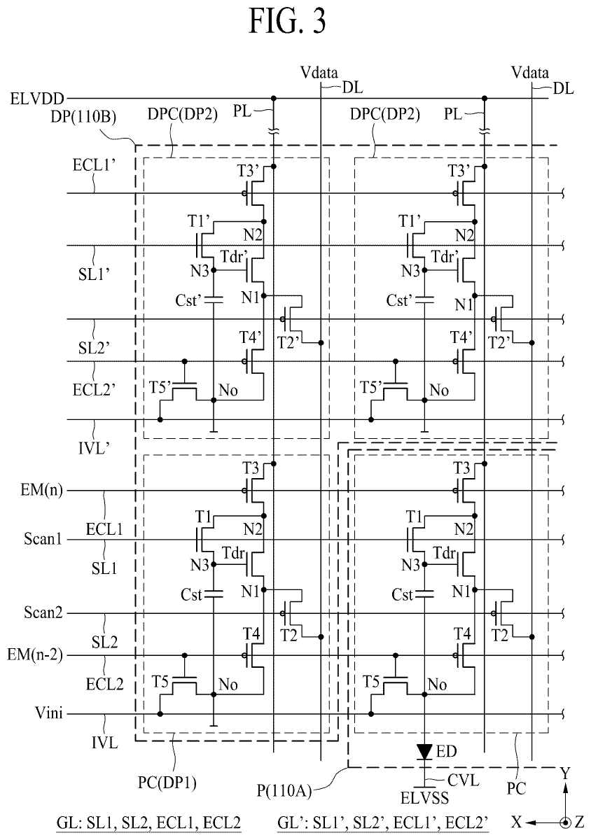

FIG. 3 is an equivalent circuit diagram illustrating configurations of a pixel, a first dummy pixel, and a second dummy pixel in a display apparatus according to an embodiment of the present disclosure.

Referring to FIG. 3, in the display apparatus according to an embodiment of the present disclosure, each of the plurality of pixels P disposed in the display pixel area 110A may include a pixel circuit PC and a light emitting device ED.

The pixel circuit PC of each of the plurality of pixels P may include a switching thin-film transistor T2 configured to supply a data voltage Vdata supplied through a data line DL to a first node N1, and a driving thin-film transistor Tdr configured to output a data current corresponding to the data voltage which is supplied from the switching thin-film transistor T2 to the light emitting device ED through an output node No based on gate-source voltages thereof (or a voltage between the gate and the source).

The pixel circuit PC of each of the plurality of pixels P according to an embodiment of the present disclosure may include a driving thin-film transistor Tdr, first to fifth thin-film transistors T1 to T5, and a storage capacitor Cst. Each of the thin-film transistors Tdr and T1 to T5 may be a thin-film transistor using any one of a polysilicon semiconductor, an amorphous silicon semiconductor, or an oxide semiconductor.

The thin-film transistors Tdr and T1 to T5 according to an embodiment of the present disclosure may be configured as a P-type polysilicon transistor. The thin-film transistors Tdr and T1 to T5 according to another embodiment of the present disclosure may be configured as an N-type oxide transistor. The thin-film transistors Tdr and T1 to T5 according to another embodiment of the present disclosure may be configured by mixing the P-type polysilicon transistor and the N-type oxide transistor.

In the pixel circuit PC, the second, third, and fourth thin-film transistors T2, T3, and T4 may be configured as a P-type LTPS (low-temperature polycrystalline silicon) transistors with a high-mobility, and the driving thin-film transistor Tdr, the first thin-film transistor T1, and the fifth thin-film transistor T5 may be configured as the N-type oxide transistors with lower off-current (leakage current) than the LTPS transistors.

The pixel P disposed in an N^{th} (N is a positive integer) horizontal line may be connected to a gate line GL including a first scan line SL1, a second scan line SL2, a first emission control line ECL1, and a second emission control line ECL2 which are disposed in an N^{th} horizontal line, and may be further connected to a data line DL, a pixel driving power line PL, a common voltage line CVL, and an initialization voltage line IVL. Each of the plurality of pixels P may be driven to include an initialization period, a sampling period, and an emission period in each frame, but is not limited thereto.

The first thin-film transistor T1 may be controlled by the first scan line SL1 of the gate line GL and may be configured to connect a third node N3 which is connected to a gate electrode of the driving thin-film transistor Tdr and a second node N2 which is connected to a drain electrode (or a second electrode) of the driving thin-film transistor Tdr. The first thin-film transistor T1 may be configured to connect the gate electrode and the drain electrode of the driving thin-film transistor Tdr during the initialization period and the sampling period in response to the first scan signal Scan1 supplied to the first scan line SL1, thereby connecting the driving thin-film transistor Tdr in a diode connection structure. The first thin-film transistor T1 which is configured as the N-type oxide transistor may be turned-on by a gate high voltage (or a gate-on voltage) of the first scan signal Scan1 and turned-off by a gate low voltage (or a gate-off voltage) of the first scan signal Scan1. For example, the first thin-film transistor T1 may be a sampling transistor, but is not limited thereto.

The second thin-film transistor T2 may be controlled by the second scan line SL2 of the gate line GL and may be configured to connect a first node N1 which is connected to the source electrode (or a first electrode) of the driving thin-film transistor Tdr and the data line DL. The second thin-film transistor T2 may be configured to apply the data voltage Vdata supplied through the data line DL to the driving thin-film transistor Tdr during the sampling period in response to the second scan signal Scan2 supplied to the second scan line SL2. The second thin-film transistor T2 which is configured as the P-type LTPS transistor may be turned-on by the gate low voltage (or a gate-on voltage) of the second scan signal Scan2 and turned-off by the gate high voltage (or a gate-off voltage) of the second scan signal Scan2. For example, the second thin-film transistor T2 may be a switching transistor, but is not limited thereto.

The third thin-film transistor T3 may be controlled by the first emission control line ECL1 of the gate line GL and may be configured to connect the second node N2 which is connected to the drain electrode of the driving thin-film transistor Tdr and a pixel driving power line PL. The third thin-film transistor T3 may be configured to apply a pixel driving voltage ELVDD supplied through the pixel driving power line PL to the driving thin-film transistor Tdr during the initialization period and the emission period in response to a first emission control signal EM(n) supplied through the first emission control line ECL1. The third thin-film transistor T3 which is configured as the P-type LTPS transistor may be turned-on by the gate low voltage (or a gate-on voltage) of the first emission control signal EM(n) and turned-off by the gate high voltage (or a gate-off voltage) of the first emission control signal EM(n). For example, the third thin-film transistor T3 may be an operation control transistor, but is not limited thereto.

The fourth thin-film transistor T4 may be controlled by the second emission control line ECL2 and may be configured to connect the first node N1 which is connected to the source electrode of the driving thin-film transistor Tdr and the output node No which is connected to an anode electrode of the light emitting device ED. The fourth thin-film transistor T4 may be configured to connect the driving thin-film transistor Tdr to the anode electrode of the light emitting device ED during the emission period in response to a second emission control signal EM(n−2) supplied through the second emission control line ECL2. The fourth thin-film transistor T4 which is configured as the P-type LTPS transistor may be turned-on by the gate low voltage (or a gate-on voltage) of the second emission control signal EM(n−2) and turned-off by the gate high voltage (or a gate-off voltage) of the second emission control signal EM(n−2). For example, the fourth thin-film transistor T4 may be an emission control transistor, but is not limited thereto.

The fifth thin-film transistor T5 may be controlled by the second emission control line ECL2 and may be configured to connect the initialization voltage line IVL and the output node No which is connected to the anode electrode of the light emitting device ED. The fifth thin-film transistor T5 may be configured to apply an initialization voltage Vini supplied from the initialization voltage line IVL to the anode electrode of the light emitting device ED during the initialization period and the sampling period except for the emission period in response to a second emission control signal EM(n−2) supplied through the second emission control line ECL2. The initialization voltage Vini may be expressed as a reference voltage. The fifth thin-film transistor T5 which is configured as the N-type oxide transistor may share a same second emission control signal EM(n−2) as the fourth thin-film transistor T4 which is configured as the P-type LTPS transistor. In contrast to the fourth thin-film transistor T4, the fifth thin-film transistor T5 may be turned-on by the gate high voltage (or a gate-on voltage) of the second emission control signal EM(n−2) and turned-off by the gate low voltage (or a gate-off voltage) of the second emission control signal EM(n−2). For example, the fifth thin-film transistor T5 may be an initialization transistor, but is not limited thereto. For example, the fourth thin-film transistor T4 and the fifth thin-film transistor T5 share the second emission control signal EM(n−2), and thus, a size of the gate driving circuit may be reduced in the display apparatus according to an embodiment of the present disclosure.

The storage capacitor Cst may be connected between the third node N3 and the output node No and may be charged with and hold a target voltage corresponding to a differential voltage (Vdata+Vth−Vini) between the data voltage Vdata which is compensated for the threshold voltage Vth of the driving thin-film transistor Tdr and the initialization voltage Vini during the sampling period, and may apply the held target voltage to the driving thin-film transistor Tdr during the emission period.

The driving thin-film transistor Tdr may include a gate electrode connected to the third node N3, a source electrode (or a first electrode) connected to the first node N1, and a drain electrode (or a second electrode) connected to the second node N2. The driving thin-film transistor Tdr may control a data current based on the target voltage held in the storage capacitor Cst and supply the data current to the light emitting device ED through the fourth thin-film transistor T4 to drive the light emitting device ED, thereby controlling a luminance of the light emitting device ED according to the amount of the data current. For example, the driving thin-film transistor Tdr may be a driving transistor.

The light emitting device ED may include the anode electrode connected to the first node N1 of the driving thin-film transistor Tdr through the fourth thin-film transistor T4, a cathode electrode connected to a common voltage line CVL to which a common voltage (or a low-potential voltage or a cathode voltage) ELVSS is applied, and a light emitting layer formed (or interposed) between the anode electrode and the cathode electrode. For example, the light emitting layer may include an emission stack structure including one or more organic light emitting layers. The light emitting device ED may emit light with luminance proportional to the amount of the data current supplied from the driving thin-film transistor Tdr through the fourth thin-film transistor T4.

In the display apparatus according to an embodiment of the present disclosure, each of the plurality of first dummy pixels DP1 disposed in the dummy pixel area 110B may include a pixel circuit PC.

The pixel circuit PC of each of the plurality of first dummy pixels DP1 may include a switching thin-film transistor T2 configured to supply a data voltage Vdata supplied through a data line DL to a first node N1, and a driving thin-film transistor Tdr configured to output a data current corresponding to the data voltage supplied from the switching thin-film transistor T2 to an output node No based on gate-source voltages thereof (or a voltage between the gate and the source). Except for that the pixel circuits PC of each of the plurality of first dummy pixels DP1 are configured without including a light emitting device ED, the pixel circuits PC of each of the plurality of first dummy pixels DP1 may be substantially a same as the pixel circuits PC of the plurality of pixels P, and thus, a repetitive description thereof is omitted.

In the display apparatus according to an embodiment of the present disclosure, each of the plurality of second dummy pixels DP2 disposed in the dummy pixel area 110B may include a dummy pixel circuit DPC.

Each dummy pixel circuit DPC of the plurality of second dummy pixels DP2 may include a dummy thin-film switching transistor (or a dummy switching transistor) T2′ configured to output a data voltage Vdata supplied through the data line DL to a first node N1, and a dummy driving thin-film transistor (or a dummy driving transistor) Tdr′ configured to output a data current corresponding to the data voltage supplied from the dummy switching thin-film transistor T2′ to an output node No based on gate-source voltages thereof (or a voltage between the gate and the source).

The dummy pixel circuit DPC of each of the plurality of second dummy pixels DP2 may include a dummy driving thin-film transistor Tdr′, first to fifth dummy thin-film transistors T1′ to T5′, and a dummy storage capacitor Cst′.

A dummy gate line GL′ and a dummy initialization voltage line IVL′ which are connected to the dummy pixel circuit DPC of each of the plurality of second dummy pixels DP2 may have an electrically floating state. For example, the dummy gate line GL′ connected to the dummy pixel circuit DPC may not be electrically connected to the gate driving circuit 200 described above with reference to FIGS. 1 and 2, and thus, may have an electrically floating state (or may be maintained in an electrically floating state). For example, a first dummy scan line SL1′, a second scan line SL2′, a first dummy emission control line ECL1′, a second dummy emission control line ECL2′, and a dummy initialization voltage line IVL′ which are connected to the dummy pixel circuit DPC of each of the plurality of second dummy pixels DP2 may each have an electrically floating state (or may be maintained in an electrically floating state).

In the dummy pixel circuit DPC of each of the plurality of second dummy pixels DP2, except that gate electrodes of the first to fifth dummy thin-film transistors T1′ to T5′ are connected to the dummy gate line GL′ and a first electrode of the fifth dummy thin-film transistor T5′ is connected to the dummy initialization voltage line IVL′, the dummy pixel circuit DPC of each of the plurality of second dummy pixels DP2 may be substantially the same as the pixel circuit PC of the plurality of pixels P, and thus, a repetitive description thereof is omitted.

The plurality of second dummy pixels DP2 include the dummy pixel circuits DPC, but unlike the plurality of pixels P, may not include the light emitting device, and thus, in the dummy pixel circuit DPC of each of the plurality of second dummy pixels DP2, the output node No may have an electrically floating state (or may be maintained in an electrically floating state). Since each of the gate line GL′ and the dummy initialization voltage line IVL′ has an electrically floating state, the plurality of second dummy pixels DP2 may also have an electrically floating state (or may be maintained in an electrically floating state).

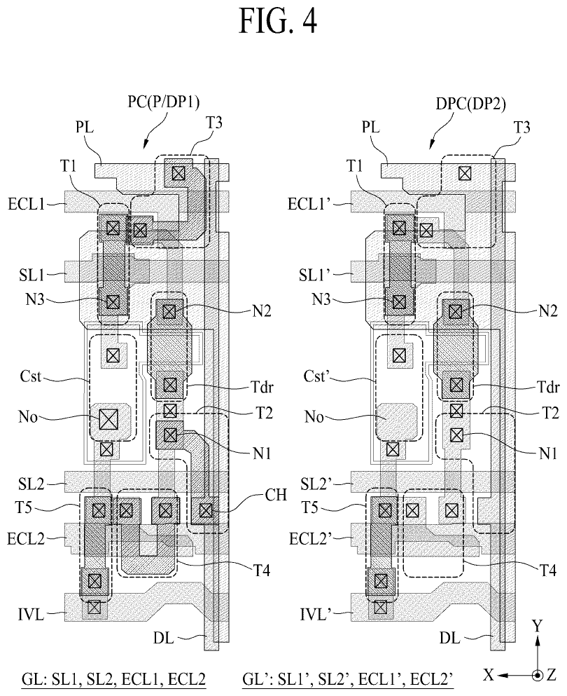

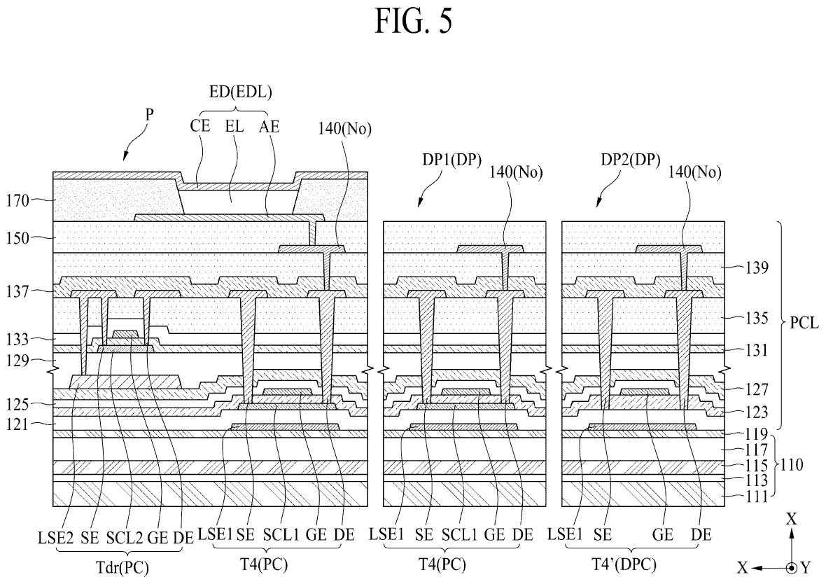

FIG. 4 is a plan view respectively illustrating layout structures of a pixel circuit and a dummy pixel circuit according to an embodiment of the present disclosure. FIG. 5 is a cross-sectional view respectively illustrating structures of a pixel, a first dummy pixel, and a second dummy pixel illustrated in FIG. 4. FIGS. 4 and 5 illustrate, as representative examples, a fourth thin film transistor T4 that is an LTPS transistor and a driving thin-film transistor Tdr that is an oxide transistor in each of: a pixel P, a pixel circuit PC of a first dummy pixel DP1, and a dummy pixel circuit DPC of a second dummy pixel DP2.

Referring to FIGS. 4 and 5, the pixel P according to an embodiment of the present disclosure may include a pixel circuit layer PCL including a pixel circuit PC disposed on a substrate 110, and a light emitting device layer EDL including a light emitting device ED disposed on the pixel circuit layer PCL.

The substrate 110 may include a first base substrate 111, an interlayer insulating layer 113, and a second base substrate 115. The first base substrate 111 and the second base substrate 115 may include glass or a flexible polymer resin. The interlayer insulating layer 113 may include an inorganic insulating material. The substrate 110 may further include a multi-buffer layer 117 disposed on the second base substrate 115. The multi-buffer layer 117 may include an inorganic insulating material.

The fourth thin-film transistor T4 disposed in the pixel P may be disposed to overlap the second emission control line ECL2.

The fourth thin-film transistor T4 may include a first light-shielding electrode LSE1 disposed on the multi-buffer layer 117, a first active buffer layer 121 covering the first light-shielding electrode LSE1, a first semiconductor layer SCL1 disposed on the first active buffer layer 121, a first gate insulating layer 123 covering the first semiconductor layer SCL1, and a gate electrode GE disposed on the first gate insulating layer 123. The first semiconductor layer SCL1 may include the LTPS.

The fourth thin-film transistor T4 may further include a plurality of first interlayer insulating layers 125 and 127, a second active buffer layer 129, a second gate insulating layer 131, and a plurality of second interlayer insulating layers 133 and 135 which are stacked on the gate electrode GE, and a source electrode SE and a drain electrode DE which are disposed on an uppermost interlayer insulating layer 135 among a plurality of first interlayer insulating layers 125 and 127 and connected to the first semiconductor layer SCL1 through a plurality of contact holes penetrating the second interlayer insulating layers 133 and 135, the second gate insulating layer 131, the second active buffer layer 129, the plurality of first interlayer insulating layers 125 and 127, and the first gate insulating layer 123. The fourth thin-film transistor T4 may be formed with a dual-gate structure.

The driving thin-film transistor Tdr may include a second light-shielding electrode LSE2 disposed on an uppermost interlayer insulating layer 127 among the plurality of first interlayer insulating layers 125 and 127, a second active buffer layer 129 covering the second light-shielding electrode LSE2, a second semiconductor layer SCL2 disposed on the second active buffer layer 129, a second gate insulating layer 131 covering the second semiconductor layer SCL2, and a gate electrode GE disposed on the second gate insulating layer 131. The second semiconductor layer SCL2 may include a metal oxide semiconductor.

The driving thin-film transistor Tdr may further include a plurality of second interlayer insulating layers 133 and 135 stacked on the gate electrode GE, and a source electrode SE and a drain electrode DE which are disposed on the uppermost interlayer insulating layer 135 among the plurality of second interlayer insulating layers 133 and 135 and connected to the second semiconductor layer SCL2 through a plurality of contact holes penetrating the plurality of second interlayer insulating layers 133 and 135 and the second gate insulating layer 131.

The source electrode SE of the driving thin-film transistor Tdr may be additionally connected to the second light-shielding electrode LSE2 through a contact hole penetrating the plurality of second interlayer insulating layers 133 and 135, the second gate insulating layer 131, and the second active buffer layer 129.

The first thin-film transistor T1 and fifth thin-film transistor T5 which are disposed in the pixel P may be formed together with the driving thin-film transistor Tdr, and thus, a repetitive description thereof is omitted. The second thin-film transistor T2 and third thin-film transistor T3 which are disposed in the pixel P may be formed together with the fourth thin-film transistor T4, and thus, a repetitive description thereof is omitted. For example, the third thin-film transistor T3 may be formed with a dual-gate structure.

The first scan line SL1 and the second emission control line ECL2 of the gate line GL, the gate electrodes GE of the driving thin-film transistor Tdr and the first and fifth thin-film transistors T1 and T5, and the initialization voltage line IVL may be formed as a second gate metal layer disposed on the second semiconductor layer SCL2.

The second scan line SL2, first emission control line ECL1 of the gate line GL, and the gate electrodes GE of the second to fourth thin-film transistors T2, T3, and T4 may be formed as a first gate metal layer disposed on the first semiconductor layer SCL1.

The source electrode and the drain electrode SE and DE of the driving thin-film transistor Tdr and the first to fifth thin-film transistors T1 to T5, and the data line DL, may be formed as a first source/drain metal layer disposed on the second gate metal layer.

The storage capacitor Cst may include a first capacitor electrode CC1 and a second capacitor electrode CC2. The first capacitor electrode CC1 of the storage capacitor Cst may be formed of the second gate metal layer and integrally formed (or one body) with the gate electrode of the driving thin-film transistor Tdr, and may be connected to the first thin-film transistor T1 through the third node N3. The second capacitor electrode CC2 of the storage capacitor Cst may be formed as a second light-shielding metal layer and may be commonly connected to the fourth and fifth thin-film transistors T4 and T5 through the output node No.

A passivation layer 137 and a first planarization layer 139 may be disposed on the fourth thin-film transistor T4. A connection electrode 140 may be formed as a second source/drain metal layer on the first planarization layer 139. The connection electrode 140 may be connected to the drain electrode DE (or source electrode SE) of the fourth thin-film transistor T4 through a contact hole penetrating the passivation layer 137 and the first planarization layer 139. The pixel driving power line PL may be formed together with the connection electrode 140 as the second source/drain metal layer on the first planarization layer 139. The pixel driving power line PL may be connected to the source electrode SE (or drain electrode DE) of the third thin-film transistor T3 through a contact hole penetrating the passivation layer 137 and the first planarization layer 139.

A second planarization layer 150 may be disposed on the connection electrode 140, and a light emitting device layer EDL may be disposed on the second planarization layer 150.

The light emitting device layer EDL may include an anode electrode AE, a light emitting layer EL, and a cathode electrode CE which are stacked on the second planarization layer 150, and may include a bank insulating layer 170 that defines an emission region (or a pixel opening region) of the light emitting layer EL on the anode electrode AE.

The bank insulating layer 170 may include black materials, light-shielding materials, or light-absorbing materials. The bank insulating layer 170 may include materials that absorb specific wavelengths. The bank insulating layer 170 may include a structure in which at least two different colored filters among a red color filter, green color filter, and blue color filter are stacked.

The anode electrode AE may be connected to the connection electrode 140 through a contact hole penetrating the second planarization layer 150. The anode electrode AE may include a plurality of conductive layers having a high-reflectivity. End portion (or an edge portion) of the anode electrode AE may be covered by the bank insulating layer 170. Accordingly, a remaining portion except for the end portion of the anode electrode AE may be defined as the emission region (or pixel opening region) of the light emitting layer EL.

The light emitting layer EL may be formed of a hole control layer, one or more organic light emitting layers, and an electron control layer stacked in order or reverse order. The hole control layer may include at least a hole transport layer among a hole injection layer and a hole transport layer, and the electron control layer may include at least an electron transport layer, among an electron transport layer and an electron injection layer.

The cathode electrode CE may be disposed on the light emitting layer EL and may be a common electrode connected along a surface of the bank insulating layer 170. The cathode electrode CE may be formed of a conductive material or a semi-transparent conductive material which have a high light transmittance. A capping layer may be further disposed on the cathode electrode CE, thereby enhancing light resonance and light emission efficiency of the light emitting device ED.

According to an embodiment of the present disclosure, an encapsulation layer may be formed (or disposed) on the light emitting device layer EDL. The encapsulation layer may be formed (or disposed) to seal the light emitting device layer EDL, prevent penetration of moisture or oxygen into the light emitting device ED, and cover particles to prevent movement (or migration) of the particles.

According to an embodiment of the present disclosure, a touch sensor array including a plurality of touch electrodes may be further disposed on the encapsulation layer. A color filter array including color filters and a black matrix or a lens array may be further disposed on the touch sensor array.

The plurality of first dummy pixels DP1 among the plurality of dummy pixels DP according to an embodiment of the present disclosure may include a pixel circuit layer PCL including a pixel circuit PC disposed in the dummy pixel area of the substrate 110. The pixel circuit layer PCL of each of the plurality of first dummy pixels DP1 may be substantially the same as the pixel circuit layer PCL of the pixel P, and thus, a repetitive description thereof is omitted. In the plurality of first dummy pixels DP1, the connection electrode 140 (or output node No) connected to the fourth thin-film transistor T4 of the pixel circuit layer PCL may be covered by the second planarization layer 150, and the light emitting device layer EDL including the light emitting device ED is not formed (or disposed) on the pixel circuit layer PCL of each of the plurality of first dummy pixels DP1.

The plurality of second dummy pixels DP2 among the plurality of dummy pixels DP according to an embodiment of the present disclosure may include a pixel circuit layer PCL including the dummy pixel circuit DPC disposed in the dummy pixel area of the substrate 110. The pixel circuit layer PCL of each of the plurality of second dummy pixels DP2 is substantially the same as the pixel circuit layer PCL of the pixel P, and thus, a brief description thereof will be given.

Each of the first dummy thin-film transistor (or a dummy sampling transistor) T1′, the fifth dummy thin-film transistor (or a dummy initialization transistor) T5′, and the dummy driving thin-film transistor (or a dummy driving transistor) Tdr′ disposed in each of the plurality of second dummy pixels DP2 may be formed together with the driving thin-film transistor Tdr disposed in the pixel P, and thus, a repetitive description thereof is omitted. The second dummy thin-film transistor (or a dummy switching transistor) T2′, the third dummy thin-film transistor (or a dummy operation control transistor) T3′, and the fourth dummy thin-film transistor (or a dummy emission control transistor) T4′ disposed in each of the plurality of second dummy pixels DP2 may be formed together with the fourth thin-film transistor T4 disposed in the pixel P, and thus, a repetitive description thereof is omitted.

The first dummy scan line SL1′ and the second dummy emission control line ECL2′ of the dummy gate line GL′, and the gate electrodes GE of the dummy driving thin-film transistor Tdr′ and the first and fifth dummy thin-film transistors T1′ and T5′ may be formed as the second gate metal layer disposed on the second semiconductor layer SCL2.

The second dummy scan line SL2′ and first dummy emission control line ECL1′ of the dummy gate line GL′, and the gate electrodes GE of the second to fourth dummy thin-film transistors T2′, T3′, and T4′ may be formed as the first gate metal layer disposed on the first semiconductor layer SCL1.

The source electrode SE and the drain electrode DE of the dummy driving thin-film transistor Tdr′ and the first to fifth dummy thin-film transistors T1′ to T5′ may be formed as the first source/drain metal layer disposed on the second gate metal layer.

In the plurality of second dummy pixels DP2, the connection electrode 140 (or output node No) connected to the fourth dummy thin-film transistor T4′ of the pixel circuit layer PCL may be covered by the second planarization layer 150, and the light emitting device layer EDL including the light emitting device ED is not formed (or disposed) on the pixel circuit layer PCL of each of the plurality of second dummy pixels DP2. Accordingly, in the plurality of second dummy pixels DP2, the connection electrode 140 (or output node No) connected to the fourth dummy thin-film transistor T4′ of the pixel circuit layer PCL may have an electrically floating state (or may be maintained in an electrically floating state).

As described above, the inventors of the present disclosure have recognized that block dim may occur due to luminance deviation caused by non-uniformity of data signals (or voltages) applied to the display pixel area due to interference between the plurality of data lines DL and the dummy pixels DP in the electrically floating state. For example, since the dummy initialization voltage line IVL′ disposed in the plurality of second dummy pixels DP2 among the plurality of dummy pixels DP has an electrically floating state, a leakage current may occur in a thin-film transistor due to charges accumulated in the insulating layer disposed in the plurality of second dummy pixels DP2, and due to this, a current path may be formed between the dummy initialization voltage line IVL′ and the plurality of data lines DL, and the block dim may occur due to luminance deviation caused by non-uniformity of data signals (or voltages) applied to the display pixel area, and thus, image quality may be deteriorated. An embodiment of the present disclosure for preventing or minimizing the block dim due to luminance non-uniformity by each region is described below.

Referring to FIGS. 4 and 5, according to an embodiment of the present disclosure, the second dummy thin-film transistor (or a dummy switching transistor) T2′ disposed in some dummy pixels among the plurality of dummy pixels DP may be electrically insulated from or physically separated from the data line DL and may not include a semiconductor layer. For example, the second dummy thin-film transistor T2′ disposed in the plurality of second dummy pixels DP2 among the plurality of dummy pixels DP may be electrically insulated from or physically separated from the data line DL and may be configured without the first semiconductor layer SCL1.

According to an embodiment of the present disclosure, the source electrode SE (or drain electrode DE) of the second thin-film transistor T2 disposed in the pixel P may be electrically connected to the data line DL through a contact hole CH. In contrast, the contact hole CH for electrically connecting the source electrode SE (or drain electrode DE) of the second dummy thin-film transistor T2′ to the data line DL is not formed in the plurality of second dummy pixels DP2. Accordingly, the second dummy thin-film transistor T2′ disposed in the plurality of second dummy pixels DP2 may be electrically insulated from or physically separated from the data line DL.

The first semiconductor layer SCL1 formed (or disposed) in the second dummy thin-film transistor T2′ disposed in the plurality of second dummy pixels DP2 may be removed through a separate patterning (or etching) process, or may not be deposited (or formed) during the deposition process of the first semiconductor layer SCL1.

Accordingly, according to an embodiment of the present disclosure, in the plurality of second dummy pixels DP2, the second dummy thin-film transistor T2′, which is electrically connected to the data line DL and the dummy pixel circuit DPC, is electrically insulated from the data line DL and formed without a semiconductor layer, and thus, since the current path between the dummy initialization voltage line IVL′ and the plurality of data lines DL is blocked (or cut off), the block dim due to luminance deviation caused by non-uniformity of data signals (or voltages) applied to the display pixel area may be prevented or minimized. Therefore, image quality of the display apparatus due to luminance uniformity by each region may be enhanced, and power consumption due to a high luminance of the display apparatus may be reduced.

Referring to FIG. 4, according to another embodiment of the present disclosure, one or more of the third dummy thin-film transistor T3′ (or the operation control transistor) and the fourth dummy thin-film transistor T4′ (or the emission control transistor) disposed in some dummy pixels among the plurality of dummy pixels DP may also not include a semiconductor layer in a same (or same manner) as the second dummy thin-film transistor T2′. For example, one or more of the third dummy thin-film transistor T3′ and the fourth dummy thin-film transistor T4′ disposed in the plurality of second dummy pixels DP2 may be configured without the first semiconductor layer SCL1. For example, in the plurality of second dummy pixels DP2, each of the second to fourth dummy thin-film transistors T2′, T3′, and T4′ disposed adjacent to the data line DL may be configured without the first semiconductor layer SCL1. Therefore, the block dim due to luminance deviation caused by non-uniform of data signals (or voltages) applied to the display pixel area may be further prevented or further minimized.

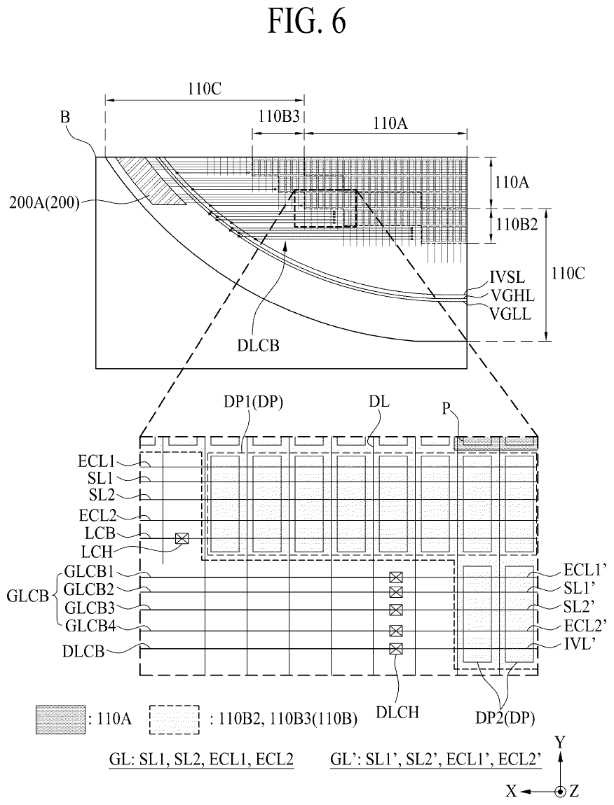

FIG. 6 is an enlarged view of a portion “B” illustrated in FIG. 1. FIG. 6 illustrates an example of an electrical connection structure for dummy lines disposed in some of dummy pixels in a display apparatus according to another embodiment of the present disclosure.

Referring to FIG. 6, in the display apparatus according to another embodiment of the present disclosure, the dummy lines disposed in some of the dummy pixels DP may not have an electrically floating state, but may have a predetermined voltage level.

One or more of the dummy lines GL′ and IVL′ disposed in each of the plurality of second dummy pixels DP2 among the plurality of dummy pixels DP may be electrically connected to a voltage supply line IVSL, VGHL, and VGLL through a dummy line connection bridge DLCB and a dummy line contact hole DLCH. For example, one end of the dummy line connection bridge DLCB may be disposed to overlap one end of the dummy line GL′ and IVL′ and may be electrically connected to the one end of the dummy line GL′ and IVL′ through the dummy line contact hole DLCH. The other end of the dummy line connection bridge DLCB may be disposed to overlap the voltage supply line IVSL, VGHL, and VGLL and may be electrically connected to the voltage supply line IVSL, VGHL, and VGLL through the dummy line contact hole DLCH. Accordingly, one or more of the dummy lines GL′ and IVL′ disposed in each of the plurality of second dummy pixels DP2 may not be an electrically floating and may be maintained at a constant voltage supplied through the voltage supply line IVSL, VGHL, and VGLL. Therefore, the current path between the dummy lines GL′ and IVL′ which are disposed in each of the plurality of second dummy pixels DP2 and the plurality of data lines DL is blocked (or cut off), and thus, the block dim due to luminance deviation caused by non-uniformity of data signals (or voltages) applied to the display pixel area may be prevented or minimized. As a result, image quality of the display apparatus due to luminance uniformity by each region may be enhanced, luminance of the display apparatus may be enhanced, and power consumption due to a high luminance of the display apparatus may be reduced.

According to an embodiment of the present disclosure, the dummy initialization voltage line IVL′ disposed in each of the plurality of second dummy pixels DP2 among the plurality of dummy pixels DP may be electrically connected to the initialization voltage supply line IVSL. For example, one or more of one end and the other end of the dummy initialization voltage line IVL′ may be electrically connected to the initialization voltage supply line IVSL through the dummy line connection bridge DLCB and the dummy line contact hole DLCH.

According to an embodiment of the present disclosure, as illustrated in FIGS. 2 and 6, the initialization voltage line IVL disposed in each of the plurality of pixels P may be electrically connected to the initialization voltage supply line IVSL. For example, one or more of one end and the other end of the initialization voltage line IVL may be electrically connected to the initialization voltage supply line IVSL through a line connection bridge LCB and a line contact hole LCH.

According to an embodiment of the present disclosure, the dummy gate line GL′ disposed in each of the plurality of second dummy pixels DP2 among the plurality of dummy pixels DP may be electrically connected to gate driving voltages line VGHL and VGLL. For example, one or more of one end and the other end of the dummy gate line GL′ may be electrically connected to the gate driving voltage lines VGHL and VGLL through a gate line connection bridge GLCB and a dummy line contact hole DLCH. The gate line connection bridge GLCB may include first to fourth gate line connection bridges GLCB1 to GLCB4.

According to an embodiment of the present disclosure, the first dummy emission control line ECL1′ of the dummy gate line GL′ disposed in each of the plurality of second dummy pixels DP2 among the plurality of dummy pixels DP may be electrically connected to a gate high voltage supply line VGHL. For example, one or more of one end and the other end of the first dummy emission control line ECL1′ may be electrically connected to the gate high voltage supply line VGHL through the first gate line connection bridge GLCB1 and the dummy line contact hole DLCH.

The first dummy scan line SL1′ of the dummy gate line GL′ disposed in each of the plurality of second dummy pixels DP2 among the plurality of dummy pixels DP may be electrically connected to a gate low voltage supply line VGLL. For example, one or more of one end and the other end of the first dummy scan line SL1′ may be electrically connected to the gate low voltage supply line VGLL through the second gate line connection bridge GLCB2 and the dummy line contact hole DLCH.

The second dummy scan line SL2′ of the dummy gate line GL′ disposed in each of the plurality of second dummy pixels DP2 among the plurality of dummy pixels DP may be electrically connected to the gate high voltage supply line VGHL. For example, one or more of one end and the other end of the second dummy scan line SL2′ may be electrically connected to the gate high voltage supply line VGHL through the third gate line connection bridge GLCB3 and the dummy line contact hole DLCH.

The second dummy emission control line ECL2′ of the dummy gate line GL′ disposed in each of the plurality of second dummy pixels DP2 among the plurality of dummy pixels DP may be electrically connected to the gate low voltage supply line VGLL. For example, one or more of one end and the other end of the second dummy emission control line ECL2′ may be electrically connected to the gate low voltage supply line VGLL through the fourth gate line connection bridge GLCB4 and the dummy line contact hole DLCH.

The dummy line connection bridge DLCB may be formed together with the connection electrode 140 described above with reference to FIG. 5.

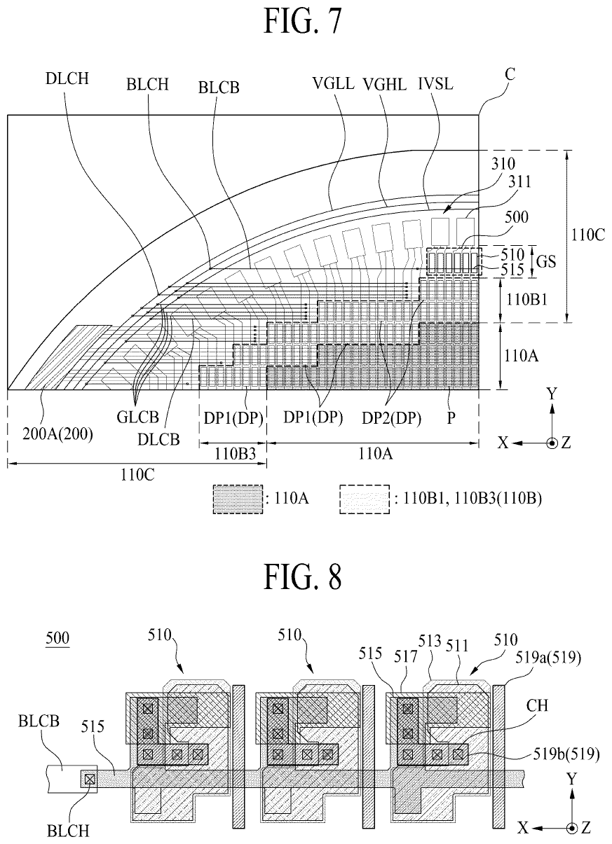

In FIG. 6, one or more of the dummy lines GL′ and IVL′ disposed in the second dummy pixel area (or an upper dummy area) 110B2 among the dummy pixel areas 110B are illustrated to be electrically connected to the voltage supply lines IVSL, VGHL, and VGLL through the dummy line connection bridge DLCB and/or the gate line connection bridge GLCB and the dummy line contact hole DLCH, but is not limited thereto. For example, as illustrated in FIG. 7, one or more of the dummy lines GL′ and IVL′ disposed in the first dummy pixel area (or a lower dummy area) 110B1 among the dummy pixel areas 110B may be electrically connected to the voltage supply lines IVSL, VGHL, and VGLL through the dummy line connection bridge DLCB and/or the gate line connection bridge GLCB and the dummy line contact hole DLCH, and thus, a repetitive description thereof is omitted.

Accordingly, the dummy initialization voltage lines IVL′ disposed in each of the plurality of second dummy pixels DP2 may not be electrically floating but may be maintained at an initialization voltage supplied through the initialization voltage supply line IVSL. Therefore, a current path between the dummy initialization voltage line IVL′ and the plurality of data lines DL is blocked (or cut off), and thus, the block dim due to luminance deviation caused by non-uniformity of data signals (or voltages) applied to the display pixel area may be prevented or minimized. As a result, image quality of the display apparatus due to luminance uniformity by each region may be enhanced, luminance of the display apparatus may be enhanced, and power consumption due to a high luminance of the display apparatus may be reduced.

In the display apparatus according to another embodiment of the present disclosure described above with reference to FIG. 6, the second dummy thin-film transistor (or dummy switching transistor) T2′ disposed in some of the dummy pixels DP among the plurality of dummy pixels DP is electrically insulated from or physically separated from the data line DL and does not include a semiconductor layer, as described above with reference to FIGS. 4 and 5. For example, the second dummy thin-film transistor T2′ disposed in each of the plurality of second dummy pixels DP2 among the plurality of dummy pixels DP may be electrically insulated from or physically separated from the data line DL and may be configured without a first semiconductor layer SCL1. Accordingly, in the display apparatus according to another embodiment of the present disclosure, the block dim due to luminance deviation caused by non-uniform of data signals (or voltages) applied to the display pixel area may be further prevented or further minimized. Therefore, image quality of the display apparatus due to luminance uniformity by each region may be enhanced, luminance of the display apparatus may be enhanced, and power consumption due to a high luminance of the display apparatus may be reduced.

FIG. 7 is an enlarged view of a portion “C” illustrated in FIG. 1. FIG. 8 is a diagram illustrating a barrier pixel part illustrated in FIG. 7. FIGS. 7 and 8 illustrate an embodiment where a barrier pixel part is additionally configured in the display apparatus described above with reference to FIG. 6. In the following description, therefore, the barrier pixel part and relevant elements will be only described, the other elements may be referred to by same reference numerals, and their repetitive descriptions are omitted. Thus, the description above with reference to FIG. 6 may be included in descriptions of FIGS. 7 and 8.

Referring to FIGS. 7 and 8, the display apparatus according to another embodiment of the present disclosure may further include a barrier pixel part 500 disposed between the time-division data output part 310 and the dummy pixel area 110B.

The barrier pixel part 500 may be disposed in a gap space GS between the time-division data output part 310 and the dummy pixel area 110B. For example, the barrier pixel part 500 may be configured to fill a predetermined ratio of an area of the gap space GS between the time-division data output part 310 and the dummy pixel area 110B. The barrier pixel part 500 may be configured to prevent over-etching that occurs during an etching (or patterning) process of the metal layer due to the gap space GS in a manufacturing process of the thin-film transistors configuring the multiplexer 311 of the time-division data output part 310. For example, in the etching process of the metal layers of the thin-film transistors configuring the multiplexer 311, the barrier pixel part 500 may block or disturb the flow of an etchant flowing to the multiplexer 311 through the gap space GS, thereby preventing over-etching of the metal layer of the thin film transistor constituting the multiplexer 311, and thus, the effect of reducing production energy through process optimization may be realized. For example, the barrier pixel part 500 may be a barrier structure, over-etching prevention structure, or dam pattern part.

The barrier pixel part 500 may include a plurality of barrier pixels 510.

The plurality of barrier pixels 510 may have a width corresponding to the dummy pixels DP disposed in the dummy pixel area 110B. The plurality of barrier pixels 510 may have a length smaller than a distance (or a shortest distance) between the time-division data output part 310 and the dummy pixel area 110B.

Each of the plurality of barrier pixels 510 may include a plurality of metal pattern layers. Each of the plurality of barrier pixels 510 may include a plurality of metal pattern layers which are stacked to correspond to a structure of a thin-film transistor formed on the substrate (or the pixel P). For example, each of the plurality of barrier pixels 510 may include a plurality of metal pattern layers which are stacked to correspond to a structure of the thin-film transistors configuring the multiplexer 311 of the time-division data output part 310.

Each of the plurality of barrier pixels 510 according to an embodiment of the present disclosure may include a shape and a stacked structure corresponding to the thin-film transistor.

Each of the plurality of barrier pixels 510 may include first to fifth metal pattern layers 511, 513, 515, 517, and 519.

The first metal pattern layer 511 may be disposed on a same layer as the second light-shielding electrode formed in the pixel circuit PC of the pixel P. For example, the first metal pattern layer 511 may be disposed on the uppermost interlayer insulating layer 127 of the plurality of first interlayer insulating layers 125 and 127. The first metal pattern layer 511 may be configured to prevent over-etching of the light-shielding electrode of the driving thin-film transistor Tdr configuring the multiplexer 311. The first metal pattern layer 511 may be covered by the second active buffer layer 129.

The second metal pattern layer 513 may be disposed on the second active buffer layer 129 to overlap the first metal pattern layer 511. For example, the second metal pattern layer 513 may entirely overlap the first metal pattern layer 511 and may have a larger size than the first metal pattern layer 511, but is not limited thereto. The second metal pattern layer 513 may be disposed on a same layer as the second semiconductor layer SCL2 of the driving thin-film transistor Tdr formed in the pixel circuit PC of the pixel P. The second metal pattern layer 513 may be configured to prevent over-etching of the semiconductor layer of the thin-film transistor configuring the multiplexer 311.

The third metal pattern layer 515 may be disposed on the second gate insulating layer 131 to overlap at least a portion of the second metal pattern layer 513. The third metal pattern layer 515 may include a first portion overlapping the second metal pattern layer 513 and a second portion not overlapping the second metal pattern layer 513. The third metal pattern layer 515 may be commonly connected to the plurality of barrier pixels 510. For example, the second metal pattern layer 515 may be a gate line of the barrier pixel part 500.

The third metal pattern layer 515 may be disposed on a same layer as the gate electrode of the driving thin-film transistor Tdr formed in the pixel circuit PC of the pixel P. The third metal pattern layer 515 may be configured to prevent over-etching of the gate electrode of the thin-film transistor configuring the multiplexer 311.

The fourth metal pattern layer 517 may be disposed on a lowermost interlayer insulating layer 133 of the second interlayer insulating layers 133 and 135 so as to overlap a portion of the third metal pattern layer 515 and a portion of the second metal pattern layer 513. The fourth metal pattern layer 517 may be disposed on a same layer as the second gate metal layer of the driving thin-film transistor Tdr formed in the pixel circuit PC of the pixel P. The fourth metal pattern layer 517 may be configured to prevent over-etching of the second gate metal layer of the thin-film transistor configuring the multiplexer 311.

The fifth metal pattern layer 519 may be disposed on the uppermost interlayer insulating layers of the second interlayer insulating layers 133 and 135 to overlap the fourth metal pattern layer 517 and the second metal pattern layer 513 and to cross the third metal pattern layer 515. The fifth metal pattern layer 519 may be disposed on a same layer as the source and drain electrodes of the driving thin-film transistor Tdr formed in the pixel circuit PC of the pixel P. The fifth metal pattern layer 519 may be configured to prevent over-etching of the source and drain electrodes of the thin-film transistor configuring the multiplexer 311.

The fifth metal pattern layer 519 may include a line pattern 519a and a contact pattern 519b.

The line pattern 519a may be disposed to cross the third metal pattern layer 515.

The contact pattern 519b may be connected to the first metal pattern layer 511 through one or more second contact holes formed in the plurality of second interlayer insulating layers 133 and 135 and may be connected to the third metal pattern layer 515 through one or more contact holes formed in the plurality of second interlayer insulating layers 133 and 135. Furthermore, the contact pattern 519b may be connected to the second metal pattern layer 513 through one or more contact holes penetrating the plurality of second interlayer insulating layers 133 and 135, the second gate insulating layer 131, and the second active buffer layer 129.

Any one of the first to fifth metal pattern layers 511, 513, 515, 517, and 519 of each of the plurality of barrier pixels 510 may be configured to be connected to the plurality of barrier pixels 510 in common. For example, the third metal pattern layer 515 of each of the plurality of barrier pixels 510 may be commonly connected to the plurality of barrier pixels 510 and may configure a barrier line 515 parallel to the dummy gate line. It will be understood that to configure a barrier line 515 is to provide a barrier line via the metal pattern layer 515.

The barrier line 515 may be electrically connected to the voltage supply lines IVSL, VGHL, and VGLL through a barrier line connection bridge BLCB and a barrier line contact hole BLCH. Accordingly, the barrier line 515 may not be electrically floating but may be maintained at a constant voltage supplied through the voltage supply lines IVSL, VGHL, and VGLL. For example, the barrier line 515 may be electrically connected to any one of the initialization voltage supply line IVSL, the gate high voltage line VGHL, and the gate low voltage line VGLL through the barrier line connection bridge BLCB and the barrier line contact hole BLCH. Accordingly, the barrier line 515 may not be electrically floating and may be maintained at any one of the initialization voltage, the gate high voltage, and the gate low voltage.

Therefore, since the barrier line 515 crossing the plurality of data lines is not electrically floating but maintained at the constant voltage, a current path between the barrier line 515 and the plurality of data lines is blocked (or cut off), and thus, the block dim due to luminance deviation caused by non-uniformity of data signals (or voltages) applied to the display pixel area may be prevented or minimized. As a result, image quality of the display apparatus due to luminance uniformity by each region may be enhanced, luminance of the display apparatus may be enhanced, and power consumption due to a high luminance of the display apparatus may be reduced.

In the display apparatus according to another embodiment of the present disclosure described above with reference to FIGS. 7 and 8, the second dummy thin-film transistor (or dummy switching transistor) T2′ disposed in some of the dummy pixels DP among the plurality of dummy pixels DP is electrically insulated from or physically separated from the data line DL and does not include a semiconductor layer, as described above with reference to FIGS. 4 and 5. For example, the second dummy thin-film transistor T2′ disposed in each of the plurality of second dummy pixels DP2 among the plurality of dummy pixels DP may be electrically insulated from or physically separated from the data line DL and may be configured without a first semiconductor layer SCL1. Accordingly, in the display apparatus according to another embodiment of the present disclosure, the block dim due to luminance deviation caused by non-uniform of data signals (or voltages) applied to the display pixel area may be further prevented or further minimized. Therefore, image quality of the display apparatus due to luminance uniformity by each region may be enhanced, luminance of the display apparatus may be enhanced, and power consumption due to a high luminance of the display apparatus may be reduced.

It will be apparent to those skilled in the art that various modifications and variations can be made in the present disclosure without departing from the spirit or scope of the disclosures. Thus, it is intended that the present disclosure covers the modifications and variations of this disclosure provided that within the scope of the claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display pixel area having a corner curved portion, a dummy pixel area adjacent to the display pixel area, and a non-display area adjacent to the dummy pixel area;
a plurality of pixels disposed at the display pixel area and electrically connected to a gate line, a data line, a pixel driving power line, and an initialization voltage line;
a plurality of dummy pixels disposed at the dummy pixel area and electrically connected to a dummy gate line, the data line, the pixel driving power line, and a dummy initialization voltage line;
an initialization voltage supply line disposed at the non-display area and electrically connected to the initialization voltage line disposed at the display pixel area and to the dummy initialization voltage line.

2. The display apparatus of claim 1, further comprising a dummy line connection bridge electrically connected between the dummy initialization voltage line disposed at the dummy pixel area and the initialization voltage supply line.

3. The display apparatus of claim 1, further comprising:
a gate driving circuit disposed at the non-display area and connected only to the gate line of each of the plurality of pixels disposed at the display pixel area;
a gate driving voltage line electrically connected to the gate driving circuit; and
a gate line connection bridge electrically connected between the dummy gate line disposed at the dummy pixel area and the gate driving voltage line.

4. The display apparatus of claim 3, wherein:
each of the plurality of dummy pixels includes a dummy pixel circuit configured to output a current corresponding to a data voltage which is supplied through the data line based on a first emission control signal, a first scan signal, a second scan signal, and a second emission control signal; and
the dummy gate line includes:
a first dummy emission control line configured to supply the first emission control signal to the dummy pixel circuit;
a first dummy scan line configured to supply the first scan signal to the dummy pixel circuit;
a second dummy scan line configured to supply the second scan signal to the dummy pixel circuit; and
a second dummy emission control line configured to supply the second emission control signal to the dummy pixel circuit.

5. The display apparatus of claim 4, wherein:
the gate driving voltage line includes a gate high voltage line supplying a gate high voltage to the gate driving circuit and a gate low voltage line supplying a gate low voltage to the gate driving circuit; and
the gate line connection bridge includes:
a first gate line connection bridge electrically connected between the first dummy emission control line and the gate high voltage line;
a second gate line connection bridge electrically connected between the first dummy scan line and the gate low voltage line;
a third gate line connection bridge electrically connected between the second dummy scan line and the gate high voltage line; and
a fourth gate line connection bridge electrically connected between the second dummy emission control line and the gate low voltage line.

6. The display apparatus of claim 4, wherein:
the dummy pixel circuit includes:
a dummy switching transistor controlled by the second scan signal and configured to supply the data voltage which is supplied through the data line to a first node;
a dummy emission control transistor controlled by the second emission control signal and connected between an output node and the first node;
a dummy driving transistor connected between the first node and a second node and configured to supply a data current corresponding to the data voltage which is supplied at the first node to the dummy emission control transistor; and
a dummy operation control transistor controlled by the first emission control signal and configured to supply a pixel driving voltage to the second node, and
the output node has an electrically floating state.

7. The display apparatus of claim 6, wherein the dummy switching transistor is electrically insulated from the data line and is formed without a semiconductor layer, and/or one or both of the dummy emission control transistor and the dummy operation control transistor are formed without a semiconductor layer.

8. The display apparatus of claim 6, wherein the dummy pixel circuit further includes:
a dummy sampling transistor controlled by the first scan signal and connected between a third node which is connected to a gate electrode of the dummy driving transistor and the second node;
a dummy initialization transistor controlled by the second emission control signal and configured to supply an initialization voltage which is supplied through the dummy initialization voltage line to the output node; and
a dummy storage capacitor formed between the gate electrode of the dummy driving transistor and the output node.

9. The display apparatus of claim 3, further comprising:
a driving integrated circuit disposed at the non-display area;
a time-division data output part electrically connected between the driving integrated circuit and the data line; and
a barrier pixel part disposed between the time-division data output part and the dummy pixel area.

10. The display apparatus of claim 9, wherein the barrier pixel part is configured to extend into an area of a gap space between the time-division data output part and the dummy pixel area at a selected ratio.

11. The display apparatus of claim 9, wherein the barrier pixel part includes a plurality of barrier pixels.

12. The display apparatus of claim 11, wherein each of the plurality of barrier pixels includes a plurality of metal pattern layers.

13. The display apparatus of claim 12, wherein the plurality of metal pattern layers are stacked to correspond to a structure of a thin-film transistor disposed at the pixel.

14. The display apparatus of claim 12, wherein
any one of the plurality of metal pattern layers configures a barrier line commonly connected to the plurality of barrier pixels.

15. The display apparatus of claim 14, wherein the barrier line is not electrically floating but maintained at a constant voltage.

16. The display apparatus of claim 14, wherein the barrier line is electrically connected to the gate driving voltage line through a barrier line connection bridge.

17. The display apparatus of claim 1, wherein:
each of the plurality of dummy pixels includes a dummy pixel circuit electrically connected to the dummy gate line, the data line, the pixel driving power line, and the dummy initialization voltage line, and
the dummy pixel circuit includes:
a dummy switching transistor configured to supply a data voltage through the data line to a first node;
a dummy emission control transistor connected between an output node and the first node;
a dummy driving transistor connected between the first node and a second node and configured to supply a data current corresponding to the data voltage which is supplied at the first node to the dummy emission control transistor; and
a dummy operation control transistor configured to supply a pixel driving voltage to the dummy driving transistor through the second node, and
the output node has an electrically floating state.

18. The display apparatus of claim 17, wherein the dummy switching transistor is electrically insulated from the data line and is formed without a semiconductor layer.

19. The display apparatus of claim 18, wherein one or both of the dummy emission control transistor and the dummy operation control transistor are formed without a semiconductor layer.

20. The display apparatus of claim 17, wherein the dummy pixel circuit further includes:
a dummy sampling transistor connected between a third node which is connected to a gate electrode of the dummy driving transistor and the second node;
a dummy initialization transistor configured to supply an initialization voltage which is supplied through the dummy initialization voltage line to the output node; and
a dummy storage capacitor formed between the gate electrode of the dummy driving transistor and the output node.
